(19) United States
(12) Patent Application Publication
(10) Pub. No.: US 2024/0219264 A1
(43) Pub. Date: Jul. 4, 2024

(54) VALIDATION OF A CONFIGURATION CHANGE OF AUTONOMOUS VEHICLE TEST PARAMETERS

(71) Applicant: GM Cruise Holdings LLC, San Francisco, CA (US)

(72) Inventor: Lynn Sarcione, Austin, TX (US)

(21) Appl. No.: 18/092,430

(22) Filed: Jan. 2, 2023

(51) Int. Cl. G01M 17/007; G06F 30/20

(52) U.S. Cl. CPC G01M 17/007; G06F 30/20

(57) ABSTRACT

The disclosed technology provides solutions for validating a configuration change of autonomous vehicle (AV) test parameter(s) by determining an impact of the configuration change on a simulation test suite. A process of the disclosed technology can include steps for receiving a first configuration of a test parameter associated with testing an AV, receiving a set of simulation scenarios from a test suite, running a predetermined number of simulations of the AV using the set of simulation scenarios, determining a first distribution with respect to repeatability based on simulation output, updating a configuration of the test parameter to generate a second configuration, running the predetermined number of simulations, determining a second distribution with respect to repeatability based on simulation output, and validating the configuration update based on a comparison between the first distribution and the second distribution. Systems and machine-readable media are also provided.

### BACKGROUND

### 1. Technical Field

The present disclosure generally relates to validating a configuration change of autonomous vehicle (AV) test parameter(s) and, more specifically, validating a configuration change of AV test parameter(s) by determining an impact of the configuration change on an AV test suite.

### 2. Introduction

An autonomous vehicle is a motorized vehicle that can navigate without a human driver. An exemplary autonomous vehicle can include various sensors, such as a camera sensor, a light detection and ranging (LIDAR) sensor, and a radio detection and ranging (RADAR) sensor, amongst others. The sensors collect data and measurements that the autonomous vehicle can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system. Typically, the sensors are mounted at fixed locations on the autonomous vehicles.

### BRIEF DESCRIPTION OF THE DRAWINGS

The various advantages and features of the present technology will become apparent by reference to specific implementations illustrated in the appended drawings. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying drawings in which:

FIG. 1 illustrates an example system environment that can be used to facilitate autonomous vehicle (AV) dispatch and operations, according to some aspects of the disclosed technology;

FIG. 2A illustrates an example distribution of a passing rate in simulations using a Robotic Operation System (ROS), according to some examples of the present disclosure;

FIG. 2B illustrates an example distribution of a passing rate in simulations using a Single Binary Runner (SBR), according to some examples of the present disclosure;

FIG. 3 illustrates an example distribution of a maximum divergence in simulations using a ROS and an SBR, according to some examples of the present disclosure;

FIG. 4 illustrates an example distribution with respect to aggregate repeatability, according to some examples of the present disclosure;

FIG. 5 illustrates an example process for validating a configuration update of an AV test parameter, according to some examples of the present disclosure; and

FIG. 6 illustrates an example processor-based system with which some aspects of the subject technology can be implemented.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

One aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

Autonomous vehicle (AV) systems are complex and need robust testing to ensure adequate safety, performance, and comfort before the AV systems can be deployed in real-world settings. In some instances, AV performance can be evaluated using AV tests designed to determine if the AV can adequately perform under certain conditions, such as by safely and efficiently navigating different driving scenarios. AV tests can include a set of programmatic routines or applications that are designed to verify and/or evaluate the performance of specific AV behaviors and/or characteristics, for example, when AV operations are performed in a simulated test environment.

Every configuration change/update of a test parameter (e.g., an operating system update, a type of Graphics Processing Units (GPUs), etc.) needs to be validated before the update can be deployed in an AV testing system. For example, when a new operating system (e.g., a Robotic Operating System (ROS) or a Single Binary Replay (SBR)) for testing an AV is developed, the testing on the new operating system can be done in a simulated environment using various test scenarios to validate the new operating system. Also, for each test scenario, the new operating system can be repeatedly and sufficiently used for testing an AV to ensure that the repeated test results in the same or similar simulation output.

In some instances, a set of tests can be bundled together as a test suite. In other words, a collection of test scenarios can be grouped together as a test suite for test execution purposes. For example, test suite A can comprise a set of tests based on having oncoming emergency vehicles in test scenarios. In another example, test suite B can comprise a set of test scenarios for testing an unprotected left turn. A test suite may have some inherent noise as some scenarios have become outdated or introduce erroneous or incorrect data. As follows, when a new configuration of a test parameter is to be used for testing an AV in a set of test scenarios from a particular test suite, a level of noise in the test suite needs to be the same or less, but not more.

Aspects of the disclosed technology provide solutions for validating a configuration change of a test parameter that is associated with testing an AV by quantifying the impact of the configuration change on a test suite. Some aspects of the instant disclosure provide solutions for validating a configuration change of a test parameter by determining how the configuration change impacts the aggregate repeatability of a test suite. In some examples, the systems and techniques described herein can identify and evaluate any noise in a test suite that may have been introduced from a configuration change of a test parameter by comparing probability distributions.

In some aspects, the systems and techniques described herein (e.g., systems, apparatuses, processes/methods, and computer-readable media) can run a plurality number of simulations, using a set of tests obtained from a particular test suite, to test pre-updated and post-updated configurations of a test parameter that is associated with testing an AV. To illustrate, a pre-updated configuration of a test parameter can be used in a simulated environment for a set of simulation scenarios stored in a test suite. For each scenario of the set of simulation scenarios, the pre-updated configuration can be used repeatedly for a predetermined number of simulations (e.g., 10 times). Based on the simulation output, the systems and techniques described herein can determine a first distribution with respect to the repeatability of one or more output parameters such as a passing rate (e.g., pass/fail rate), a maximum divergence distance (e.g., an AV pose divergence), a unified safety score (USS), a simulation safety proxy, an average velocity of an AV in simulation, a comfort proxy, a crawl time, a test error, a time-to-collision, or any applicable simulation output metrics of execution. Further, a post-updated configuration of the test parameter can be used in a simulated environment for testing an AV in the same set of simulation scenarios. The post-updated configuration of the test parameter can be used for testing an AV in each scenario in the set of simulation scenarios repeatedly for the same number of simulations (e.g., 10 times). Based on the simulation output, the systems and techniques described herein can determine a second distribution with respect to the repeatability of the same output parameter.

In some examples, the systems and techniques described herein can compare the first distribution associated with the pre-updated configuration of a test parameter and the second distribution associated with the post-updated configuration of the test parameter to determine if the configuration update has introduced/added noise to the test suite. In some cases, the comparison between the first and second distributions can include comparing statistical characteristics (e.g., a mean, a standard deviation, a variance, etc.) to determine the similarity between these two distributions. A substantial difference between the first and second distributions can be an indication that the configuration update of the test parameter has introduced noise to the test suite. In other words, the degree of similarity between the first distribution associated with the pre-updated configuration of a test parameter and the second distribution associated with the post-updated configuration of the test parameter is below a threshold (e.g., a predetermined similarity threshold), it can be inferred that the repeatability of having the same simulation output in the same test suite has been impacted by the configuration update of the test parameter and therefore, that the configuration update has introduced noise into the test suite. In other words, as long as the same (or similar) repeatability (e.g., a percentage of having the same output) has been achieved in testing for two different configurations of the test parameter, regardless of the quality of the output, it can be determined that the level of noise has not been changed and therefore, a configuration change of a test parameter from one to another has been validated.

In some aspects, a Kolmogorov-Smirnov (KS) test can be further used to determine a probability that the first distribution associated with the pre-updated configuration of a test parameter is equivalent to the second distribution associated with the post-updated configuration of the test parameter. A KS test can measure the probability that observations from two distributions (e.g., the first distribution and the second distribution) are taken from the same distribution by measuring the distance between empirical distributions. A probability below a threshold can indicate that the configuration update of a test parameter has an impact on the repeatability of simulation output and has introduced/added noise to the test suite.

In some cases, in response to a determination that the noise has been added to the test suite (e.g., noise that is out of a threshold range), the configuration update can be evaluated to figure out what about the configuration update of a test parameter has prevented the testing from resulting in the same results. Also, a specific test scenario that may have the discrepancy in repeatability can be further evaluated to determine how the configuration update of a test parameter has affected the simulation output and whether the test scenario is outdated or includes erroneous/incorrect data.

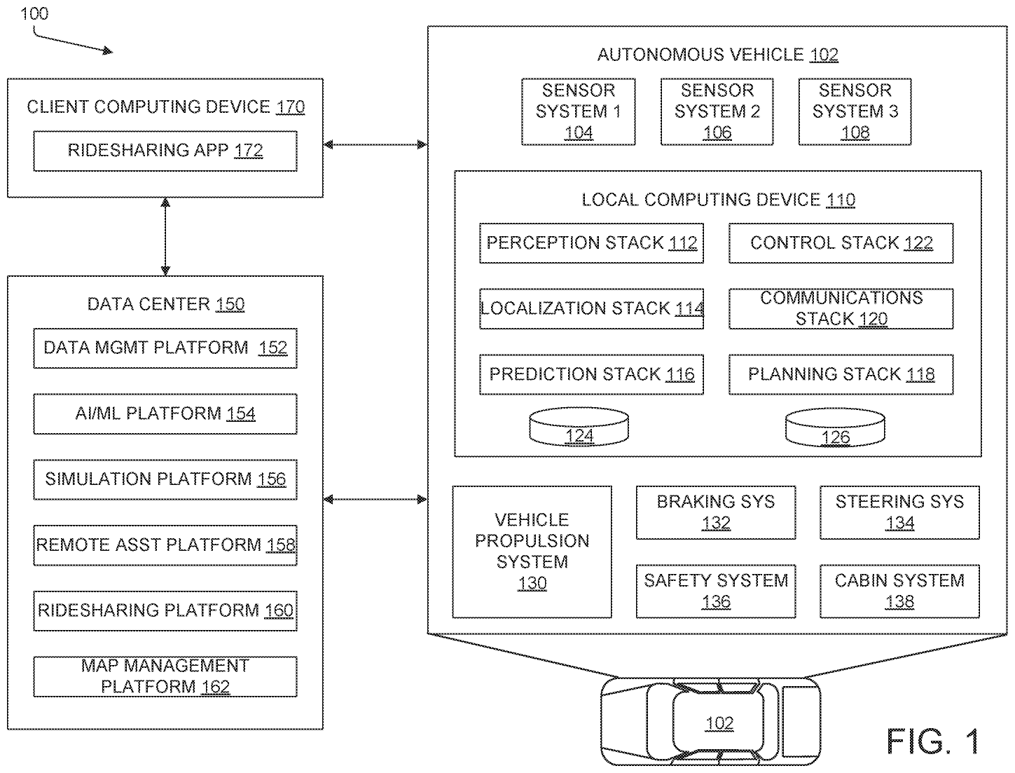

FIG. 1 is a diagram illustrating an example autonomous vehicle (AV) environment 100, according to some examples of the present disclosure. One of ordinary skill in the art will understand that, for the AV management system 100 and any system discussed in the present disclosure, there can be additional or fewer components in similar or alternative configurations. The illustrations and examples provided in the present disclosure are for conciseness and clarity. Other examples may include different numbers and/or types of elements, but one of ordinary skill the art will appreciate that such variations do not depart from the scope of the present disclosure.

In this example, the AV management system 100 includes an AV 102, a data center 150, and a client computing device 170. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

The AV 102 can navigate roadways without a human driver based on sensor signals generated by multiple sensor systems 104, 106, and 108. The sensor systems 104-108 can include one or more types of sensors and can be arranged about the AV 102. For instance, the sensor systems 104-108 can include Inertial Measurement Units (IMUs), cameras (e.g., still image cameras, video cameras, etc.), light sensors (e.g., LIDAR systems, ambient light sensors, infrared sensors, etc.), RADAR systems, GPS receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 can be a camera system, the sensor system 106 can be a LIDAR system, and the sensor system 108 can be a RADAR system. Other examples may include any other number and type of sensors.

The AV 102 can also include several mechanical systems that can be used to maneuver or operate the AV 102. For instance, the mechanical systems can include a vehicle propulsion system 130, a braking system 132, a steering system 134, a safety system 136, and a cabin system 138, among other systems. The vehicle propulsion system 130 can include an electric motor, an internal combustion engine, or both. The braking system 132 can include an engine brake, brake pads, actuators, and/or any other suitable componentry configured to assist in decelerating the AV 102. The steering system 134 can include suitable componentry configured to control the direction of movement of the AV 102 during navigation. The safety system 136 can include lights and signal indicators, a parking brake, airbags, and so forth. The cabin system 138 can include cabin temperature control systems, in-cabin entertainment systems, and so forth. In some examples, the AV 102 might not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

The AV 102 can include a local computing device 110 that is in communication with the sensor systems 104-108, the mechanical systems 130-138, the data center 150, and the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108; and so forth. In this example, the local computing device 110 includes a perception stack 112, a mapping and localization stack 114, a prediction stack 116, a planning stack 118, a communications stack 120, a control stack 122, an AV operational database 124, and an HD geospatial database 126, among other stacks and systems.

The perception stack 112 can enable the AV 102 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 126, other components of the AV, and other data sources (e.g., the data center 150, the client computing device 170, third party data sources, etc.). The perception stack 112 can detect and classify objects and determine their current locations, speeds, directions, and the like. In addition, the perception stack 112 can determine the free space around the AV 102 (e.g., to maintain a safe distance from other objects, change lanes, park the AV, etc.). The perception stack 112 can identify environmental uncertainties, such as where to look for moving objects, flag areas that may be obscured or blocked from view, and so forth. In some examples, an output of the prediction stack can be a bounding area around a perceived object that can be associated with a semantic label that identifies the type of object that is within the bounding area, the kinematic of the object (information about its movement), a tracked path of the object, and a description of the pose of the object (its orientation or heading, etc.).

The mapping and localization stack 114 can determine the AV's position and orientation (pose) using different methods from multiple systems (e.g., GPS, IMUs, cameras, LIDAR, RADAR, ultrasonic sensors, the HD geospatial database 126, etc.). For example, in some cases, the AV 102 can compare sensor data captured in real-time by the sensor systems 104-108 to data in the HD geospatial database 126 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LIDAR). If the mapping and localization information from one system is unavailable, the AV 102 can use mapping and localization information from a redundant system and/or from remote data sources.

The prediction stack 116 can receive information from the localization stack 114 and objects identified by the perception stack 112 and predict a future path for the objects. In some examples, the prediction stack 116 can output several likely paths that an object is predicted to take along with a probability associated with each path. For each predicted path, the prediction stack 116 can also output a range of points along the path corresponding to a predicted location of the object along the path at future time intervals along with an expected error value for each of the points that indicates a probabilistic deviation from that point.

The planning stack 118 can determine how to maneuver or operate the AV 102 safely and efficiently in its environment. For example, the planning stack 118 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 102 from one point to another and outputs from the perception stack 112, localization stack 114, and prediction stack 116. The planning stack 118 can determine multiple sets of one or more mechanical operations that the AV 102 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 118 can select from multiple backup plans to carry out. For example, while preparing to change lanes to turn right at an intersection, another vehicle may aggressively cut into the destination lane, making the lane change unsafe. The planning stack 118 could have already determined an alternative plan for such an event. Upon its occurrence, it could help direct the AV 102 to go around the block instead of blocking a current lane while waiting for an opening to change lanes.

The control stack 122 can manage the operation of the vehicle propulsion system 130, the braking system 132, the steering system 134, the safety system 136, and the cabin system 138. The control stack 122 can receive sensor signals from the sensor systems 104-108 as well as communicate with other stacks or components of the local computing device 110 or a remote system (e.g., the data center 150) to effectuate operation of the AV 102. For example, the control stack 122 can implement the final path or actions from the multiple paths or actions provided by the planning stack 118. This can involve turning the routes and decisions from the planning stack 118 into commands for the actuators that control the AV's steering, throttle, brake, and drive unit.

The communications stack 120 can transmit and receive signals between the various stacks and other components of the AV 102 and between the AV 102, the data center 150, the client computing device 170, and other remote systems. The communications stack 120 can enable the local computing device 110 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communications stack 120 can also facilitate the local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 126 can store HD maps and related data of the streets upon which the AV 102 travels. In some examples, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include three-dimensional (3D) attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls lane can include geospatial information of traffic signal lights, traffic signs, and other road objects and related attributes.

The AV operational database 124 can store raw AV data generated by the sensor systems 104-108, stacks 112-122, and other components of the AV 102 and/or data received by the AV 102 from remote systems (e.g., the data center 150, the client computing device 170, etc.). In some examples, the raw AV data can include HD LIDAR point cloud data, image data, RADAR data, GPS data, and other sensor data that the data center 150 can use for creating or updating AV geospatial data or for creating simulations of situations encountered by AV 102 for future testing or training of various machine learning algorithms that are incorporated in the local computing device 110.

The data center 150 can include a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and/or any other network. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes a data management platform 152, an Artificial Intelligence/Machine Learning (AI/ML) platform 154, a simulation platform 156, a remote assistance platform 158, and a ridesharing platform 160, and a map management platform 162, among other systems.

The data management platform 152 can be a “big data” system capable of receiving and transmitting data at high velocities (e.g., near real-time or real-time), processing a large variety of data and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), and/or data having other characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, the map management platform 162, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, the map management platform 162, and other platforms and systems. The simulation platform 156 can replicate a variety of driving environments and/or reproduce real-world scenarios from data captured by the AV 102, including rendering geospatial information and road infrastructure (e.g., streets, lanes, crosswalks, traffic lights, stop signs, etc.) obtained from a cartography platform (e.g., map management platform 162); modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system such as, for example and without limitation, a server, desktop computer, laptop computer, tablet computer, smartphone, smart wearable device (e.g., smartwatch, smart eyeglasses or other Head-Mounted Display (HMD), smart ear pods, or other smart in-ear, on-ear, or over-ear device, etc.), gaming system, or any other computing device for accessing the ridesharing application 172. The client computing device 170 can be a customer's mobile computing device or a computing device integrated with the AV 102 (e.g., the local computing device 110). The ridesharing platform 1160 can receive requests to pick up or drop off from the ridesharing application 1172 and dispatch the AV 1102 for the trip.

Map management platform 162 can provide a set of tools for the manipulation and management of geographic and spatial (geospatial) and related attribute data. The data management platform 152 can receive LIDAR point cloud data, image data (e.g., still image, video, etc.), RADAR data, GPS data, and other sensor data (e.g., raw data) from one or more AVs 102, Unmanned Aerial Vehicles (UAVs), satellites, third-party mapping services, and other sources of geospatially referenced data. The raw data can be processed, and map management platform 162 can render base representations (e.g., tiles (2D), bounding volumes (3D), etc.) of the AV geospatial data to enable users to view, query, label, edit, and otherwise interact with the data. Map management platform 162 can manage workflows and tasks for operating on the AV geospatial data. Map management platform 162 can control access to the AV geospatial data, including granting or limiting access to the AV geospatial data based on user-based, role-based, group-based, task-based, and other attribute-based access control mechanisms. Map management platform 162 can provide version control for the AV geospatial data, such as to track specific changes that (human or machine) map editors have made to the data and to revert changes when necessary. Map management platform 162 can administer release management of the AV geospatial data, including distributing suitable iterations of the data to different users, computing devices, AVs, and other consumers of HD maps. Map management platform 162 can provide analytics regarding the AV geospatial data and related data, such as to generate insights relating to the throughput and quality of mapping tasks.

In some embodiments, the map viewing services of map management platform 162 can be modularized and deployed as part of one or more of the platforms and systems of the data center 150. For example, the AI/ML platform 154 may incorporate the map viewing services for visualizing the effectiveness of various object detection or object classification models, the simulation platform 156 may incorporate the map viewing services for recreating and visualizing certain driving scenarios, the remote assistance platform 158 may incorporate the map viewing services for replaying traffic incidents to facilitate and coordinate aid, the ridesharing platform 160 may incorporate the map viewing services into the client application 172 to enable passengers to view the AV 102 in transit en route to a pick-up or drop-off location, and so on.

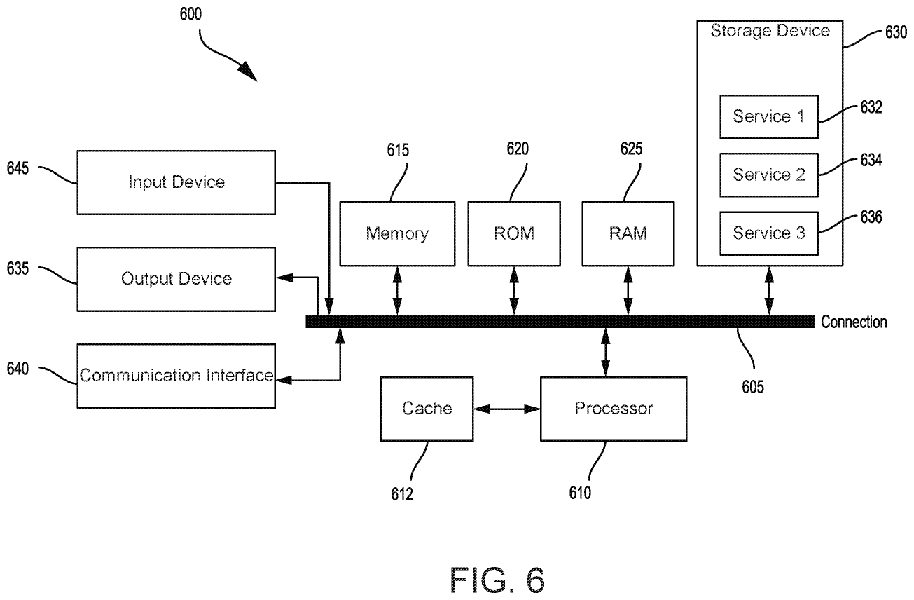

While the autonomous vehicle 102, the local computing device 110, and the autonomous vehicle environment 100 are shown to include certain systems and components, one of ordinary skill will appreciate that the autonomous vehicle 102, the local computing device 110, and/or the autonomous vehicle environment 100 can include more or fewer systems and/or components than those shown in FIG. 1. For example, the autonomous vehicle 102 can include other services than those shown in FIG. 1 and the local computing device 110 can also include, in some instances, one or more memory devices (e.g., RAM, ROM, cache, and/or the like), one or more network interfaces (e.g., wired and/or wireless communications interfaces and the like), and/or other hardware or processing devices that are not shown in FIG. 1. An illustrative example of a computing device and hardware components that can be implemented with the local computing device 110 is described below with respect to FIG. 6.

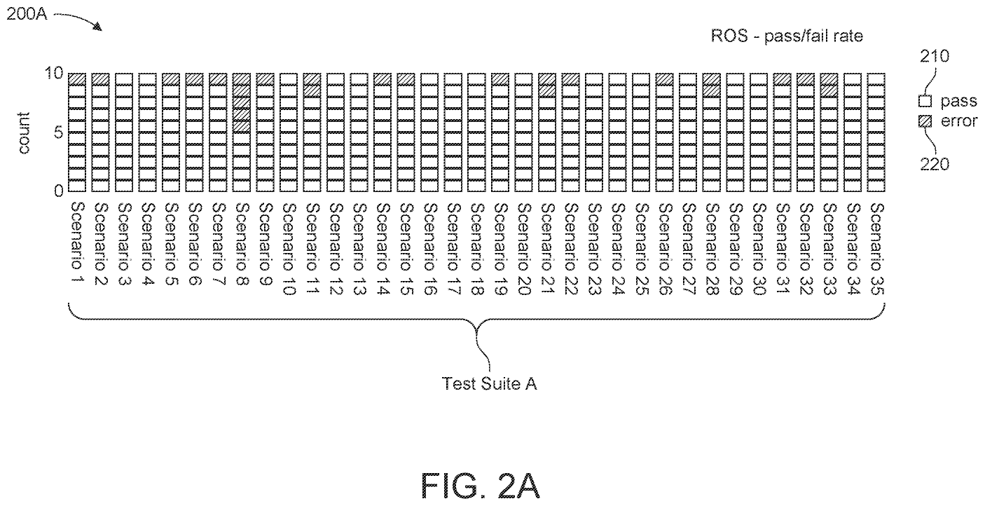

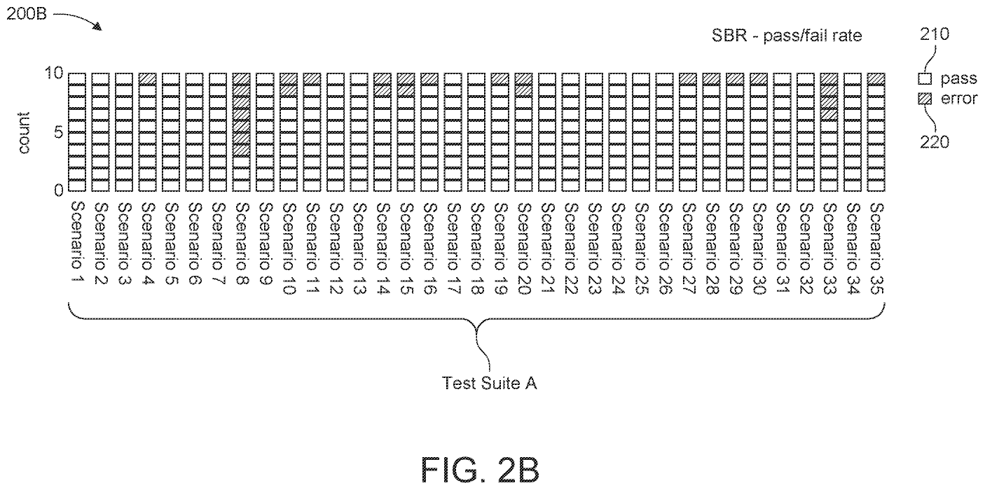

FIG. 2A illustrates an example distribution of a passing rate 200A for testing an AV (e.g., AV 102 as illustrated in FIG. 1) in simulations with a Robotic Operating System (ROS) execution using a set of test scenarios from test suite A. A ROS is an AV software framework, which includes software stacks that communicate with other software stacks, for example asynchronously at different timings. As shown on the x-axis in FIG. 2A, test suite A comprises 35 scenarios (e.g., from Scenario 1 to Scenario 35). While test suite A includes 35 scenarios as an example, any applicable number of test scenarios can be included in a single test suite. Further, the same test scenario can be included in more than one test suite. For example, Scenario 1 in test suite A can be also part of test suite B, test suite C, and/or test suite N.

In FIG. 2A, the y-axis corresponds to a number of repeatability run (e.g., a count of a test run). In this example, each scenario has been run 10 times to evaluate a passing rate for the ROS execution. Block 210 indicates when the AV performance has passed. Block 220 indicates when the AV performance has failed. For example, in Scenario 1, the AV performance has passed 9 times out of 10 runs (e.g., a passing rate of 90%). In Scenario 3, the AV performance has passed 100%. As follows, the repeatability (i.e., a likelihood of having the same output) for Scenario 1 is 0.9 and for Scenario 3, the repeatability is 1.

FIG. 2B illustrates an example distribution of a passing rate 200B for testing an AV in simulations with a Single Binary Replay (SBR) execution using a set of test scenarios from test suite A. In this example, the configuration of the test parameter (e.g., an operating system) has been updated an SBR execution, instead of a ROS execution. An SBR is an AV software framework, in which communications between software stacks are done in a single process, for example without interrupting one another. For example, an SBR can convert the test execution to a single binary instead of allowing multiple dynamic threads and reconfiguration. The same set of test scenarios (e.g., from Scenario 1 to Scenario 35) from test suite A has been used for testing an AV with the SBR execution. In this example, each scenario has been run 10 times to evaluate a passing rate for the SBR execution. In Scenario 1, the AV performance has passed 100%. In Scenario 3, the AV performance has passed 100%. Based on the example distribution 200A of FIG. 2A and the example distribution 200B of FIG. 2B, the repeatability distributions for a passing rate can be compared when the operating system for testing the AV has been changed from the ROS execution to the SBR execution.

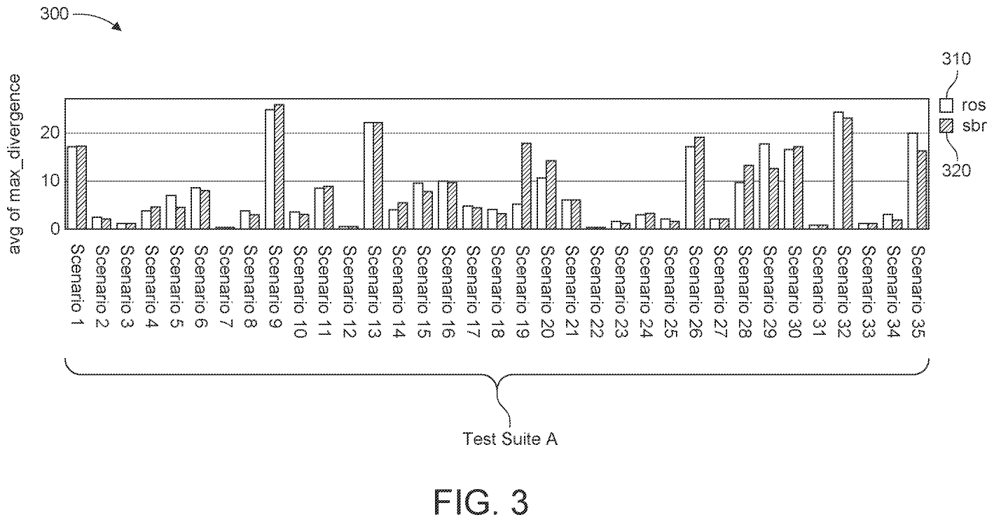

FIG. 3 illustrates an example distribution of a maximum divergence 300 for testing an AV with two different operating systems (e.g., a ROS execution and an SBR execution) in simulations. In this example, a different parameter/simulation output metric (e.g., a maximum divergence) of the simulation output has been evaluated for the ROS execution and the SBR execution in simulations using the same set of test scenarios as used in FIGS. 2A and 2B. A maximum divergence indicates the distance between the pose of the AV in simulation and the pose of the AV in ground truth data (e.g., how far off of the path the AV moved in simulation). The y-axis corresponds to the average of a maximum divergence in Scenarios 1-35. As illustrated, bar 310 shows the simulation results of testing with the ROS execution. Bar 320 shows the simulation results of testing with the SBR execution.

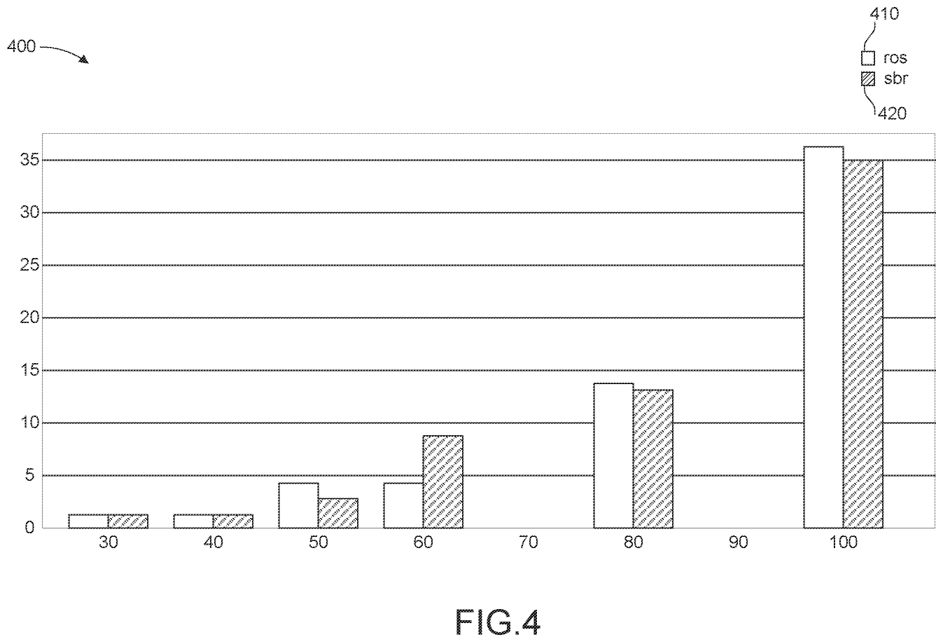

FIG. 4 illustrates an example distribution with respect to aggregate repeatability 400. Each scenario (e.g., from Scenario 1 to Scenario 35) has been used in the predetermined number of simulations (e.g., 10 runs) to evaluate various simulation output metrics such as a passing rate as shown in FIGS. 2A and 2B or a maximum divergence as shown in FIG. 3. A distribution with respect to aggregate repeatability can be plotted based on distributions of one or more simulation output metrics (e.g., a passing rate, a maximum divergence, etc.) in aggregate. In FIG. 4, the x-axis corresponds to repeatability in percentage (%) and the y-axis corresponds to a number of counts (e.g., a number of scenarios). As shown, the aggregate repeatability distributions for the pre-updated configuration (e.g., the ROS execution 410) and the post-updated configuration (e.g., the SBR execution 420) can be compared. More specifically, the systems and techniques of the present disclosure can measure overall repeatability across the entire test suite (e.g., test suite A comprising Scenarios 1 to 35). Based on the simulation outputs (e.g., simulation output metrics), each value of the simulation outputs can be compared to one another. Furthermore, if the difference between those two outputs is less than a repeatability threshold, the systems and techniques of the present disclosure can count the instance as repeatable. Also, the systems and techniques can determine that the instance is not repeatable if the difference between those two outputs exceeds a repeatability threshold. The number of repeatable instances can be divided by the total number of instances to get repeatability in percentage (%) (e.g., the number of repeatable instances/the total number of instances*100). As shown in FIG. 4, a histogram of an aggregate repeatability 400 for the ROS execution 410 and the SBR execution 420 can be plotted for comparison.

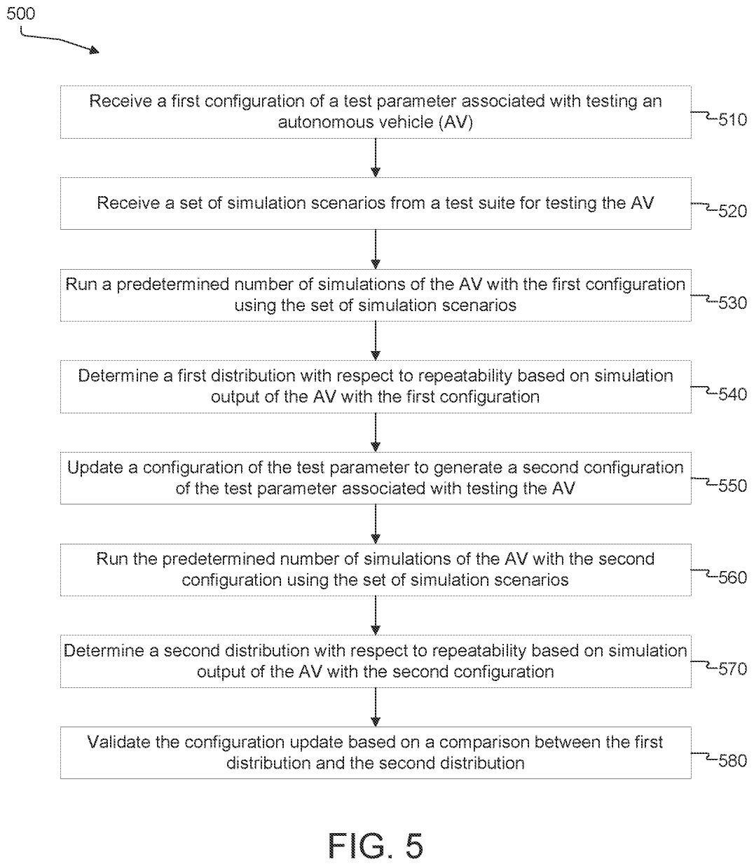

FIG. 5 illustrates a flow diagram of an example process 500 for validating a configuration update of a test parameter associated with testing an AV. Although the example process 500 depicts a particular sequence of operations, the sequence may be altered without departing from the scope of the present disclosure. For example, some of the operations depicted may be performed in parallel or in a different sequence that does not materially affect the function of the process 500. In other examples, different components of an example device or system that implements the process 500 may perform functions at substantially the same time or in a specific sequence.

At step 510, process 500 includes receiving a first configuration of a test parameter associated with testing an AV. For example, the systems and techniques described herein can receive a first configuration (e.g., a ROS execution) for an operating system that can be used for testing an AV (e.g., AV 102 as illustrated in FIG. 1).

At step 520, process 500 includes receiving a set of simulation scenarios from a test suite for testing the AV. For example, the systems and techniques described herein can receive a set of simulation scenarios from a selected test suite (e.g., Scenarios 1 to 35 stored in test suite A as illustrated in FIGS. 2A-4). In some examples, a test suite can be a collection of test scenarios that are grouped together based on test execution purposes. For example, test suite A can be a collection of test scenarios that are directed to opening an AV door, an AV yielding and blocking rear-following non-player characters (NPCs), etc.

At step 530, process 500 includes running a predetermined number of simulations of the AV with the first configuration using the set of simulation scenarios. For example, as illustrated in FIG. 2A, the testing based on the ROS execution can be repeatedly run 10 times using Scenarios 1-35 in test suite A to evaluate the pass/fail of the AV performance.

At step 540, process 500 includes determining a first distribution with respect to repeatability based on simulation output of the AV with the first configuration. For example, as shown in FIG. 2A, a distribution with respect to repeatability for a passing rate (e.g., example distribution 200A) can be determined. In another example, as shown in FIG. 3A, a distribution with respect to repeatability for a maximum divergence of a pose of the AV (e.g., example distribution 200A) can be determined.

At step 550, process 500 includes updating a configuration of the test parameter to generate a second configuration of the test parameter associated with testing the AV. For example, the test parameter can be updated from the first configuration to the second configuration. The configuration update can include a configuration change in at least one of an operating system (e.g., from a ROS execution to an SBR execution or vice versa, as illustrated in FIGS. 2A-4), a Graphics Processing Unit (GPU), or any test parameter associated with testing AV 102.

At step 560, process 500 includes running the predetermined number of simulations of the AV with the second configuration using the set of simulation scenarios. For example, as illustrated in FIG. 2B, the testing based on the SBR execution can be repeatedly run 10 times using Scenarios 1-35 in test suite A to evaluate the pass/fail of the AV performance.

At step 570, process 500 includes determining a second distribution with respect to repeatability based on simulation output of the AV with the second configuration. For example, as shown in FIG. 2B, a distribution with respect to repeatability for a passing rate (e.g., example distribution 200B) can be determined. In another example, as shown in FIG. 3A, a distribution with respect to repeatability for a maximum divergence of a pose of the AV (e.g., example distribution 300) can be determined.

In some aspects, when more than one parameter of the simulation output (e.g., simulation output metrics such as a passing rate, a maximum divergence, etc.) is evaluated, an aggregate repeatability distribution can be determined (e.g., example distribution 400 as illustrated in FIG. 4).

At step 580, process 500 includes validating the configuration update based on a comparison between the first distribution and the second distribution. In some examples, validating the configuration update can include comparing the first distribution and the second distribution to determine if the configuration update has introduced/added noise into the test suite.

In some cases, the comparison between the first distribution and the second distribution includes comparing statistical characteristics (e.g., mean, standard deviation, variance, etc.) of the first distribution and the second distribution. As previously noted, a degree of difference in statistical characteristics can indicate the degree of impact that the configuration update has on the test suite (e.g., the level of noise added to the test suite due to the configuration update).

In some aspects, the comparison between the first distribution and the second distribution is based on a Kolmogorov-Smirnov (KS) test. The KS test can determine a probability that the first distribution is equivalent to the second distribution. In other words, the KS test measures the probability that observations from two distributions (e.g., a comparison between the first distribution and the second distribution) are taken from the same distribution, measuring the distance between empirical distributions. As previously noted, a KS test can measure the probability that observations from two distributions (e.g., one associated with the pre-updated configuration of a test parameter and another associated with the post-updated configuration of the test parameter) are taken from the same distribution by measuring the distance between empirical distributions. In some examples, a probability being below a threshold can indicate that the configuration update of the AV has an impact on the repeatability of simulation output and has introduced/added noise to the test suite.

In some cases, in response to a determination that the noise has been added to the test suite (e.g., noise that is out of a threshold range), the configuration update can be evaluated to figure out what about the configuration update has prevented the testing from resulting in the same results. Also, a specific test scenario that may have the discrepancy in the repeatability can be further evaluated to determine how the configuration update has affected the simulation output and whether the test scenario is outdated or includes erroneous/incorrect data. If it is determined that the level of noise in the test suite has remained the same or within the reasonable range, the configuration update can be implemented in AV testing systems.

FIG. 6 illustrates an example processor-based system with which some aspects of the subject technology can be implemented. For example, processor-based system 600 can be any computing device making up, the local computing device 110, the data center 150, the client computing device 170, or any component thereof in which the components of the system are in communication with each other using connection 605. Connection 605 can be a physical connection via a bus, or a direct connection into processor 610, such as in a chipset architecture. Connection 605 can also be a virtual connection, networked connection, or logical connection.

In some embodiments, computing system 600 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 600 includes at least one processing unit (Central Processing Unit (CPU) or processor) 610 and connection 605 that couples various system components including system memory 615, such as Read-Only Memory (ROM) 620 and Random-Access Memory (RAM) 625 to processor 610. Computing system 600 can include a cache of high-speed memory 612 connected directly with, in close proximity to, or integrated as part of processor 610.

Processor 610 can include any general-purpose processor and a hardware service or software service, such as services 632, 634, and 636 stored in storage device 630, configured to control processor 610 as well as a special-purpose processor where software instructions are incorporated into the actual processor design. Processor 610 may essentially be a completely self-contained computing system, containing multiple cores or processors, a bus, memory controller, cache, etc. A multi-core processor may be symmetric or asymmetric.

To enable user interaction, computing system 600 includes an input device 645, which can represent any number of input mechanisms, such as a microphone for speech, a touch-sensitive screen for gesture or graphical input, keyboard, mouse, motion input, speech, etc. Computing system 600 can also include output device 635, which can be one or more of a number of output mechanisms known to those of skill in the art. In some instances, multimodal systems can enable a user to provide multiple types of input/output to communicate with computing system 600. Computing system 600 can include communications interface 640, which can generally govern and manage the user input and system output. The communication interface may perform or facilitate receipt and/or transmission wired or wireless communications via wired and/or wireless transceivers, including those making use of an audio jack/plug, a microphone jack/plug, a Universal Serial Bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a Radio-Frequency Identification (RFID) wireless signal transfer, Near-Field Communications (NFC) wireless signal transfer, Dedicated Short Range Communication (DSRC) wireless signal transfer, 802.11 Wi-Fi® wireless signal transfer, Wireless Local Area Network (WLAN) signal transfer, Visible Light Communication (VLC) signal transfer, Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer signal transfer, ultraviolet light signal transfer, wireless signal transfer along the electromagnetic spectrum, or some combination thereof.

Communication interface 640 may also include one or more Global Navigation Satellite System (GNSS) receivers or transceivers that are used to determine a location of the computing system 600 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 630 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a Compact Disc (CD) Read Only Memory (CD-ROM) optical disc, a rewritable CD optical disc, a Digital Video Disk (DVD) optical disc, a Blu-ray Disc (BD) optical disc, a holographic optical disk, another optical medium, a Secure Digital (SD) card, a micro SD (microSD) card, a Memory Stick® card, a smartcard chip, a EMV chip, a Subscriber Identity Module (SIM) card, a mini/micro/nano/pico SIM card, another Integrated Circuit (IC) chip/card, Random-Access Memory (RAM), Atatic RAM (SRAM), Dynamic RAM (DRAM), Read-Only Memory (ROM), Programmable ROM (PROM), Erasable PROM (EPROM), Electrically Erasable PROM (EEPROM), flash EPROM (FLASHEPROM), cache memory (L1/L2/L3/L4/L5/L#), Resistive RAM (RRAM/ReRAM), Phase Change Memory (PCM), Spin Transfer Torque RAM (STT-RAM), another memory chip or cartridge, and/or a combination thereof.

Storage device 630 can include software services, servers, services, etc., that when the code that defines such software is executed by the processor 610, it causes the system 600 to perform a function. In some embodiments, a hardware service that performs a particular function can include the software component stored in a computer-readable medium in connection with the necessary hardware components, such as processor 610, connection 605, output device 635, etc., to carry out the function.

Embodiments within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network Personal Computers (PCs), minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

Illustrative examples of the disclosure include:

Aspect 1. A system comprising: at least one memory; and at least one processor coupled to the at least one memory, the at least one processor configured to: receive a first configuration of a test parameter associated with testing an autonomous vehicle (AV); receive a set of simulation scenarios from a test suite for testing the AV; run a predetermined number of simulations of the AV with the first configuration using the set of simulation scenarios; determine a first distribution with respect to repeatability based on simulation output of the AV with the first configuration; update a configuration of the test parameter to generate a second configuration of the test parameter associated with testing the AV; run the predetermined number of simulations of the AV with the second configuration using the set of simulation scenarios; determine a second distribution with respect to repeatability based on simulation output of the AV with the second configuration; and validate the configuration update based on a comparison between the first distribution and the second distribution.

Aspect 2. The system of Aspect 1, wherein validating the configuration update includes comparing the first distribution and the second distribution to determine if the configuration update introduced noise into the test suite.

Aspect 3. The system of Aspect 1 or 2, wherein updating the configuration of the AV includes a configuration change in at least one of an operating system and a Graphics Processing Unit (GPU) associated with testing the AV.

Aspect 4. The system of Aspects 1 to 3, wherein the repeatability includes a likelihood of having the same simulation output in the predetermined number of simulations.

Aspect 5. The system of Aspects 1 to 4, wherein the simulation output is associated with a passing rate of the AV.

Aspect 6. The system of Aspects 1 to 5, wherein the simulation output is associated with a maximum divergence of a pose of the AV.

Aspect 7. The system of Aspects 1 to 6, wherein the comparison between the first distribution and the second distribution is based on a Kolmogorov-Smirnov (KS) test.

Aspect 8. The system of Aspects 1 to 7, wherein the comparison between the first distribution and the second distribution includes comparing statistical characteristics of the first distribution and the second distribution.

Aspect 9. The system of Aspect 8, wherein the statistical characteristics include at least one of a mean, a standard deviation, and a variance.

Aspect 10. A method comprising: receiving a first configuration of a test parameter associated with an autonomous vehicle (AV); receiving a set of simulation scenarios from a test suite for testing the AV; running a predetermined number of simulations of the AV with the first configuration using the set of simulation scenarios; determining a first distribution with respect to repeatability based on simulation output of the AV with the first configuration; updating a configuration of the test parameter to generate a second configuration of the test parameter associated with testing the AV; running the predetermined number of simulations of the AV with the second configuration using the set of simulation scenarios; determining a second distribution with respect to repeatability based on simulation output of the AV with the second configuration; and validating the configuration update based on a comparison between the first distribution and the second distribution.

Aspect 11. The method of Aspect 10, wherein validating the configuration update includes comparing the first distribution and the second distribution to determine if the configuration update introduced noise into the test suite.

Aspect 12. The method of Aspect 10 or 11, wherein updating the configuration of the AV includes a configuration change in at least one of an operating system, a hardware component, and a software component associated with the AV.

Aspect 13. The method of Aspects 10 to 12, wherein the repeatability includes a likelihood of having the same simulation output in the predetermined number of simulations.

Aspect 14. The method of Aspects 10 to 13, wherein the simulation output is associated with a passing rate of the AV.

Aspect 15. The method of Aspects 10 to 14, wherein the simulation output is associated with a maximum divergence of a pose of the AV.

Aspect 16. The method of Aspects 10 to 15, wherein the comparison between the first distribution and the second distribution is based on a Kolmogorov-Smirnov (KS) test.

Aspect 17. The method of Aspects 10 to 16, wherein the comparison between the first distribution and the second distribution includes comparing statistical characteristics of the first distribution and the second distribution.

Aspect 18. The method of Aspect 17, wherein the statistical characteristics include at least one of a mean, a standard deviation, and a variance.

Aspect 19. A non-transitory computer-readable storage medium comprising at least one instruction for causing a computer or processor to: receive a first configuration of a test parameter associated with testing an autonomous vehicle (AV); receive a set of simulation scenarios from a test suite for testing the AV; run a predetermined number of simulations of the AV with the first configuration using the set of simulation scenarios; determine a first distribution with respect to repeatability based on simulation output of the AV with the first configuration; update a configuration of the test parameter to generate a second configuration of the test parameter associated with testing the AV; run the predetermined number of simulations of the AV with the second configuration using the set of simulation scenarios; determine a second distribution with respect to repeatability based on simulation output of the AV with the second configuration; and validate the configuration update based on a comparison between the first distribution and the second distribution.

Aspect 20. The non-transitory computer-readable storage medium of Aspect 19, wherein validating the configuration update includes comparing the first distribution and the second distribution to determine if the configuration update introduced noise into the test suite.

Aspect 21. A system comprising means for performing operations in accordance with any one of Aspects 1 to 9.

What is claimed is:

1. A system comprising:
at least one memory; and
at least one processor coupled to the at least one memory, the at least one processor configured to:
receive a first configuration of a test parameter associated with testing an autonomous vehicle (AV);
receive a set of simulation scenarios from a test suite for testing the AV;
run a predetermined number of simulations of the AV with the first configuration using the set of simulation scenarios;
determine a first distribution with respect to repeatability based on simulation output of the AV with the first configuration;
update a configuration of the test parameter to generate a second configuration of the test parameter associated with testing the AV;
run the predetermined number of simulations of the AV with the second configuration using the set of simulation scenarios;
determine a second distribution with respect to repeatability based on simulation output of the AV with the second configuration; and
validate the configuration update based on a comparison between the first distribution and the second distribution.

2. The system of claim 1, wherein validating the configuration update includes comparing the first distribution and the second distribution to determine if the configuration update introduced noise into the test suite.

3. The system of claim 1, wherein updating the configuration of the AV includes a configuration change in at least one of an operating system and a Graphics Processing Unit (GPU) associated with testing the AV.

4. The system of claim 1, wherein the repeatability includes a likelihood of having the same simulation output in the predetermined number of simulations.

5. The system of claim 1, wherein the simulation output is associated with a passing rate of the AV.

6. The system of claim 1, wherein the simulation output is associated with a maximum divergence of a pose of the AV.

7. The system of claim 1, wherein the comparison between the first distribution and the second distribution is based on a Kolmogorov-Smirnov (KS) test.

8. The system of claim 1, wherein the comparison between the first distribution and the second distribution includes comparing statistical characteristics of the first distribution and the second distribution.

9. The system of claim 8, wherein the statistical characteristics include at least one of a mean, a standard deviation, and a variance.

10. A method comprising:
receiving a first configuration of a test parameter associated with testing an autonomous vehicle (AV);
receiving a set of simulation scenarios from a test suite for testing the AV;
running a predetermined number of simulations of the AV with the first configuration using the set of simulation scenarios;
determining a first distribution with respect to repeatability based on simulation output of the AV with the first configuration;
updating a configuration of the test parameter to generate a second configuration of the test parameter associated with testing the AV;
running the predetermined number of simulations of the AV with the second configuration using the set of simulation scenarios;
determining a second distribution with respect to repeatability based on simulation output of the AV with the second configuration; and
validating the configuration update based on a comparison between the first distribution and the second distribution.

11. The method of claim 10, wherein validating the configuration update includes comparing the first distribution and the second distribution to determine if the configuration update introduced noise into the test suite.

12. The method of claim 10, wherein updating the configuration of the AV includes a configuration change in at least one of an operating system and a Graphics Processing Unit (GPU) associated with testing the AV.

13. The method of claim 10, wherein the repeatability includes a likelihood of having the same simulation output in the predetermined number of simulations.

14. The method of claim 10, wherein the simulation output is associated with a passing rate of the AV.

15. The method of claim 10, wherein the simulation output is associated with a maximum divergence of a pose of the AV.

16. The method of claim 10, wherein the comparison between the first distribution and the second distribution is based on a Kolmogorov-Smirnov (KS) test.

17. The method of claim 10, wherein the comparison between the first distribution and the second distribution includes comparing statistical characteristics of the first distribution and the second distribution.

18. The method of claim 17, wherein the statistical characteristics include at least one of a mean, a standard deviation, and a variance.

19. A non-transitory computer-readable storage medium comprising at least one instruction for causing a computer or processor to:
receive a first configuration of a test parameter associated with testing an autonomous vehicle (AV);
receive a set of simulation scenarios from a test suite for testing the AV;
run a predetermined number of simulations of the AV with the first configuration using the set of simulation scenarios;
determine a first distribution with respect to repeatability based on simulation output of the AV with the first configuration;
update a configuration of the test parameter to generate a second configuration of the test parameter associated with testing the AV;
run the predetermined number of simulations of the AV with the second configuration using the set of simulation scenarios;
determine a second distribution with respect to repeatability based on simulation output of the AV with the second configuration; and
validate the configuration update based on a comparison between the first distribution and the second distribution.

20. The non-transitory computer-readable storage medium of claim 19, wherein validating the configuration update includes comparing the first distribution and the second distribution to determine if the configuration update introduced noise into the test suite.
